(19) United States
(12) Patent Application Publication
(10) Pub. No.: US 2010/0265655 A1
(43) Pub. Date: Oct. 21, 2010

(54) CASE FOR A DIVE COMPUTER

(75) Inventors: Lukas Metzler, Appenzell (CH); Markus Mock, Uster (CH); Ernst Voellm, Kilchberg (CH)

Correspondence Address: WEINGARTEN, SCHURGIN, GAGNEBIN & LEBOVICI LLP, TEN POST OFFICE SQUARE, BOSTON, MA, 02109, US

(73) Assignee: UEMIS AG, Adiswil (CH)

(21) Appl. No.: 12/681,026

(22) PCT Filed: Sep. 30, 2008
(86) PCT No.: PCT/EP2008/008293

§ 371 Date: Jul. 8, 2010

(30) Foreign Application Priority Data
Oct. 2, 2007 (DE) 10 2007 047 133.7

(51) Int. Cl. H05K 5/00; B63C 11/02

(52) U.S. Cl. 361/679.55

(57) ABSTRACT

The invention relates to a case for a dive computer that is worn by a scuba diver during dives. Said dive computer comprises a display device for displaying dive-related data that are visible from outside the case, actuation devices of the dive computer that can be actuated from outside the case and fastening devices for fastening the dive computer on the scuba diver or on his/her equipment. The case interior of the dive computer is configured in such a manner that the forces acting upon the dive computer due to the water pressure are compensated to at least some degree.

This invention concerns a case for a dive computer with a display device, activation devices and devices to attach the case to the diver or his gear.

Dive computers support the diver in planning and completing dives. During a dive, the dive computer continually detects the depth and time at least, and determines the nitrogen saturation in the diver's body. These values and the information detected by the dive computer about the dive, like for example the decompression time necessary when surfacing, are displayed to the diver by the dive computer.

Due to the high pressures that act on the dive computer as the diving depth increases, the cases of dive computers are designed to be very sturdy. U.S. Pat. No. 7,123,549 shows one known case design and discloses a diver's watch with a pressure sensor. U.S. Pat. No. 5,956,291 concerns a dive computer that is filled with air in one form of embodiment and with a silicone-based gel in another. With larger dimensions, an air-filled case design would be necessary, according to this publication, to absorb the pressure exerted on it. Larger cases are therefore usually filled with viscous media like gel or oil. But the expense of making dive computers filled with media is relatively high.

Larger cases without filling can mostly compensate for only low water pressures. As a result, relatively small display devices are frequently used on dive computers, and when they are used under water, they are often difficult for the diver to read with high water turbidity. To allow the diver to see the values displayed correctly, only the most important data are displayed on small displays. Other data detected in the dive computer, knowledge of which can also be important to the diver, are displayed only when called up or when threshold values are exceeded. If the diver sees such information too late, he can get into dangerous situations.

There are various activation devices known to turn the dive computer on and off, to select functions, change settings, etc. Thus, for example, push buttons are used that are designed so they cannot be activated unintentionally by the diver or by the water pressure. The tight pressure switches frequently used for this reason make it even harder to activate the dive computer with diving gloves on. The activating elements represent a mechanical connection from the diver to the components inside the dive computer. They therefore project through the case, so special consideration must also be given to an inner seal on that element.

It is also known how to place contact switches on the dive computer, whereby if the fingers of one hand touch two switches at the same time, a conductive connection is created that serves to activate the dive computer. However, such contact switches cannot be activated with diving gloves on. Another type of dive computer activation is shown by U.S. Pat. No. 5,760,691, which shows a measuring device for divers in which a display light is turned on by knocking on or accelerating the dive computer.

Another function of the dive computer case is to provide a way of attaching it to the diver or his gear. Dive computers that are designed as consoles are usually connected to the high-pressure hose by means of a connecting line. The end of the connecting line turned away from the high-pressure hose is built directly into the case of the dive computer, in which devices for measuring the pressure in the diver's compressed air tank are placed. Dive computers that are worn by the diver on his wrist must be designed so that such a connection between the diver and the dive computer is made.

The compression, which increases with the depth, of the arm and the diver's suit, which is frequently between the arm and the diver's watch, reduces the range of the arm and, as a result, frequently loosens the tight connection of the dive computer. Elastic plastic bands with built-in extension elements or metal bands are mostly used as bracelets, and before the dive they can be placed on the arm barely tight enough to overcome the reduction in the range of the arm and potentially the diver's suit when diving in greater depths.

The goal of this invention is to provide an improved case for a dive computer which has improved functions compared to the known cases, especially to compensate for the water pressure exerted on the dive computer.

The invention achieves this goal with the subject of Claim 1. Advantageous improvements are the subject of the subclaims.

The solution to the problem is a case for a dive computer with a display device, activating devices and attachment devices whose insides are designed so that the forces that are exerted on the dive computer by water pressure when diving, are at least partly compensated by the case. In the case design in the invention, the components of the dive computer that are not completely surrounded by the case are integrated into the case so that they spread the water pressure acting on them over the largest possible surface in the case. The case in the invention, due to the advantageous design of the inside of the case, acts as a unit that balances the forces introduced by the water pressure, which largely compensates for the forces acting on the components of the dive computer.

Compared to the components in the known dive computer cases, the components in the dive computer case in the invention can be exposed to higher pressures. As a result, the case in the invention in dive computers allows the use of dive computer components with large surfaces whose use has not been possible until now or only at great expense.

The case in the invention has the individual components of the dive computer built into a preferably molded case. In one preferred embodiment, the inside of the case is designed to provide a defined hollow space, which preferably has functional properties, like, for example, allowing access to certain components or serving as a pressure-measurement chamber. In another preferred embodiment, such functional hollow spaces are preferably filled with a medium that has a high modulus of compression (oil, silicone, etc.) and thus serves to compensate for the forces exerted on the case. The design of the hollow-space architecture is thus preferably oriented at static viewpoints. Because it is largely possible to freely determine the shape of the housing when molding it, there are also large free spaces in the design of a dive computer.

When the dive computer case in the invention is produced, the individual components of the dive computer are preferably arranged in a casting mold with signal and power connections, depending on their intended purpose and—if necessary, after other preparatory measures—molded with a suitable material. Various requirements are made of the case material: in the temperature range to which the dive computer can be exposed, it preferably has the heat-expansion properties of properties for molded components. Also, the material is preferably non-conductive, resistant to salt water and has adequate strength properties and good castability. Suitable case materials are preferably plastics, but also preferably nonconductive metals and metal alloys.

Preferably, a protective coating is applied to individual components or some part of the component that has insulating or damping properties. It is also preferred to seal the edges of partly molded components, like for example the display device or connectors. These seals preferably have damping properties. It is especially preferred to produce a glued connection between the case material and along the edge of the component. In areas where hollow spaces are provided inside the case, cores are placed in the casting mold and are taken out again after the case has hardened.

The advantage of the design for the inside of the case in the invention, through which the forces exerted by the water pressure are at least partly compensated, also results from the bidirectional transfer of forces between the components and the case material. This is achieved by the flat connection of the components to the case, which is preferably expanded only at less stressed points of hollow spaces which are preferably filled with not very compressible media. This also makes it possible to integrate large-format displays. Because of the good compensation of forces, larger color displays can also be used as display devices on the cases in the invention, which can hardly be used on known dive computer cases because of the stress on the display device.

Large-format displays on the case in the invention are preferably provided with scratch protection over large surfaces. The material used for the scratch protection is preferably hardened glass. Besides scratch protection on the surface of the display device, scratch protection also supports, with a large supporting surface, the distribution of forces over a large area that act on the display device and hence the forces introduced into the case.

The display device preferably also has a touch screen function independent of the scratch protection arrangement. This function can be activated, for example, by means of analog-resistive, capacitive or other touch screen technology. Scratch protection is preferably used as a functional element of the touch screen function. Preferably, it provides that the touch screen function be deactivated during dives to prevent unintentional activation. If it is to be used with the gloves frequently worn during diving, it makes sense to adjust the range of functions for this, like increasing the [size of the] buttons, for example.

Another advantage of the case in the invention is that function elements like attachment devices of the like can easily be made on the outside of it. Thus, for example, a holder can be molded into the housing for a pen that is needed depending on the touch screen function system. Likewise, other attachment devices like grid marks for positioning and/or attaching the dive computer case to other devices or attaching and/or positioning elements on the dive computer case and design features or surface structures can be made largely as desired.

The design of the dive computer case in the invention also makes it possible to integrate preferably large solar elements in the case, so maintenance-free energy is supplied to the dive computer connected to a built-in battery, like for example a lithium-polymer battery or the like. Since dives are frequently made in sunny vacation areas, at least a substantial portion of the energy needs of the dive computer can be covered by means of built-in solar cells. For extra energy needed, preferably a battery connection is provided on the case in the invention, which is preferably only accessible at the connection and is also built into the case in the invention.

With the battery-charging connection, preferably energy produced by other solar cells, is also stored in the dive computer. It is especially preferred that such other solar cells be placed on parts of accessories of the dive computer, like for example on a docking station, a storage container for the dive computer or other dive utensils. The accessory parts are preferably also special solar accessories, like, for example, folding solar panels, on which solar cells are arranged. The connection for the process of charging the dive computer battery can be made either via a docking station or by means of a charge connection built into the case.

It is especially preferred to have built-in devices in the case for transferring data from a computer device to the dive computer and/or from the dive computer to a computer device. Also, with the integration of the interface devices necessary for this, the case design in this invention offers clearly improved integration and compensation for the pressure on the components compared to the known dive computer cases. The interfaces can be both wireless connections and thus devices that can be wholly integrated into the case or plug-in connections, like for example, W-LAN, infrared or Bluetooth transmitters/receivers or plug-in jacks for USB connections and the like whose connection surfaces must be accessible from outside the case.

In one preferred embodiment, the dive computer case is designed so it can be used in a docking station. Preferably, the plug-in connectors for the interfaces on the dive computer are integrated into this docking station in such a way that a connection is produced when the dive computer is used. It is especially preferred to integrate both data and power connections in a docking station in order to make it possible to transmit data and supply power in parallel when the dive computer is used.

As already described above, when the case in the invention is produced, it is relatively simple to adjust the exterior design of the case and especially to make its functional and design elements, such as attachment devices or grid marks. Thus, the case is preferably designed so that additional devices, such as receiver systems for satellite navigation systems, for example, can easily be attached to them using grid marks.

In one preferred embodiment, the case is preferably designed with its functional or design elements so that a top made for it can be attached to it. The case in the invention with such a top can be arranged in terms of color, shape and surface structure. Preferably, this kind of a top can also be personalized, by putting a logo or engraving on it that identifies the owner or the group or dive station that he/she belongs to, for example.

In addition, attachment devices can also preferably be built directly into a case designed according to the invention. In one model of the dive computer, in the form of an air-integrated dive console, preferably a connecting device, which couples a connecting line from the high-pressure hose with the measurement chamber in the dive console, is molded directly into the case. The pressure transmitted through this connection into the case is absorbed by it in the same way and likewise compensates for the forces exerted by the water pressure from the outside on the dive computer. It is especially advantageous that additional sealing expense can be avoided by molding the necessary pressure sensor in the dive computer case.

The case design in the invention also allows different attachment devices to be made on the case to attach the dive computer to the diver or his gear. These include attachment elements, for example, that are connected to attachment devices built on the housing. On a dive computer that is worn by the diver on his/her arm, the bracelet in the known dive computers is usually attached on both sides by means of a pin running crosswise through the bracelet to so-called lugs on the housing. On the case in the invention, such lugs can be designed as projections or defined by a depression in between. The lugs built into the case also have openings for pins. When this type of case is molded, the shape of the lugs is built into the mold in the invention.

In one alternative embodiment, attachment elements, like bracelets, are molded directly with the dive computer case and glued on. This makes the connection between the attachment element and the dive computer very reliable. Such a glued-on connection between the bracelet and the case is especially advantageous on bracelets that are elastic, especially longitudinally.

One preferred embodiment of a bracelet that is very elastic longitudinally is composed of several strips or elements running parallel in the longitudinal direction. Elastic bracelets with a relatively low modulus of elasticity are preferably used for bracelets of dive computers. A modulus of elasticity in the range from 0.1 to 0.0001 GPa and especially the range from 0.01 to 0.0001 GPa has proven very good. Such bracelets can be stretched relatively hard without an extreme increase in the return spring force. To prevent overextension of such elastic bands, a non-stretchable band is preferably integrated into a bracelet so that the bracelet can only be elongated as far as is allowed by the non-stretchable band. Using such bracelets has the advantage that a diver can attach the dive computer before the dive to a highly stretched bracelet both directly on his/her arm and also over the dive suit without too much pressure on the arm.

As the diving depth increases, the pressure on the arm and on the compressible diving suit rises, decreasing the range of the arm including the diving suit under the dive computer bracelet. Then, there is a return extension of the elastic bracelet which is possible to the extent necessary only with sufficient prior stretching. As a result, because of the preferred design of the bracelet, for a dive computer, even when diving at greater depths, the hold on the diver's arm is secure.

In one preferred embodiment, the high elasticity required for this application with relatively low return spring force is achieved not only by the property of the material used, but through the design of the band. Thus, the elastic coil used as a band element is made out of a metal alloy, which has a relatively low spring constant and provides the elasticity for the bracelet.

Materials with the elasticity features required for the bracelet of a dive computer are usually sensitive to overextension. As already described, such an elastic band or band element is preferably combined with one or more second bands or band elements made out of a material that preferably has a low modulus of elasticity but high strength. Preferably, such a material is integrated into the bracelet so when the bracelet is not stretched, it is folded and preferably pushes in the longitudinal direction. The length of the second band is preferably dimensioned and connected to the first band so that the first elastic band cannot be stretched out over its elasticity limit.

Each attachment device for a dive computer case must be connected to the case securely, since this connection can be exposed to greater stresses during a dive, for example, on contact with a dive partner or an object like rocks or shipwrecks. Losing the dive computer during a dive puts the diver in a dangerous situation. The principle described for a stretchable bracelet that has the capacity for great adjustment to changing circumferences and lengths for the bracelet or for another attachment device, is, if necessary, also claimed independently from the dive computer case described here.

The integration of activation devices makes high requirements on a dive computer case, since dive computers must be used reliably in an environment with high water pressure from outside the case. A case made according to the invention for a dive computer makes it possible to integrate activation devices as required. The activation elements of the dive computer itself must be easy to use, even if the user is wearing diving gloves, for example. High requirements are also made when the diver activates the components inside the case with activation devices from the pressure-induced space outside the dive computer case. An insufficient seal on the devices for the case or unwanted use of the activation element can trigger situations dangerous for the diver.

The invention provides for the use of activation devices that have a signal unit that is preferably placed completely inside a closed case and connected to a signal-processing device of the dive computer. Such a signal unit is preferably activated by means of an activation element, which is placed on the outside of the dive computer case exposed to the water pressure and has no mechanical connection to the inside of the dive computer.

It is especially preferred to use slide switches, which can also be used safely with diving gloves and which are insensitive to the high water pressure acting on them. Preferably, these activation devices use the principle of the Hall Effect. In it, an electric voltage hits a line with power flowing through it, as soon as it is in a stationary magnetic field. In the invention, the line with power flowing through it, i.e., the signal unit of the activation device, is placed inside the case in which it is preferably molded in full or in part. There is therefore a mechanical connection of the signal unit through the case wall to the outside.

The activation element, into which a permanent magnet is preferably built, is mounted so it can move on the housing and can therefore move there, preferably in translation, on a guide made on the housing. In one end position of the activation element is the signal unit of the activation device, which is built into the housing, in the magnetic field of the activation element. In the signal unit, there is now a Hall voltage, which is fed to a signal-processing device on the dive computer. If the activation element is in a switched-on position, in which the signal unit is not in its magnetic field, then there is no Hall voltage on the signal unit of the activation device. As a result, no signal is transmitted to the signal-processing device of the dive computer.

In one preferred embodiment of a dive computer, these activation elements are arranged and wired so that at least two switches are always necessary to use a function. Here it is provided that these preferably two activation elements are always set so that an activation element always remains in the operating position. Thus, at least one signal unit with current flowing through it is in the magnetic field of the accompanying activation element which results in a voltage that also remains when exterior magnetic fields have an effect on the dive computer. This largely rules out a problem with the device being activated by outside magnetic fields. This principle described for activation devices for devices that are particularly closed to their environment and their way of operating shown is also claimed independently of the dive computer described here, if necessary.

The case for the dive computer in the invention, compared to known dive computer cases, allows advantageous integration of activation elements, preferably the slide switches described by at least partly molding the components into the case. Stresses exerted on the case are therefore at least partly offset without influencing the activation elements. Especially advantageous is the absence of sealing measures directly on the two-part activation device. Thus, the activation element, which preferably runs on guide rails made on the outside of the case, can be exposed to water pressure, while the signal unit with power flowing through it is built completely into the case.

The advantages of the case in the invention for a dive computer that have been described are derived from the design shown above, which at least partly offsets the forces exerted by the water pressure on the dive computer. Integrating the components of the dive computer into the housing here improves the absorption and flow of the forces exerted by the water pressure through the case. In connection with the free spaces in terms of shape, the functionality is improved compared to the known cases.

Other advantages, features and possibilities of using this invention will be seen from the description below along with the figures.

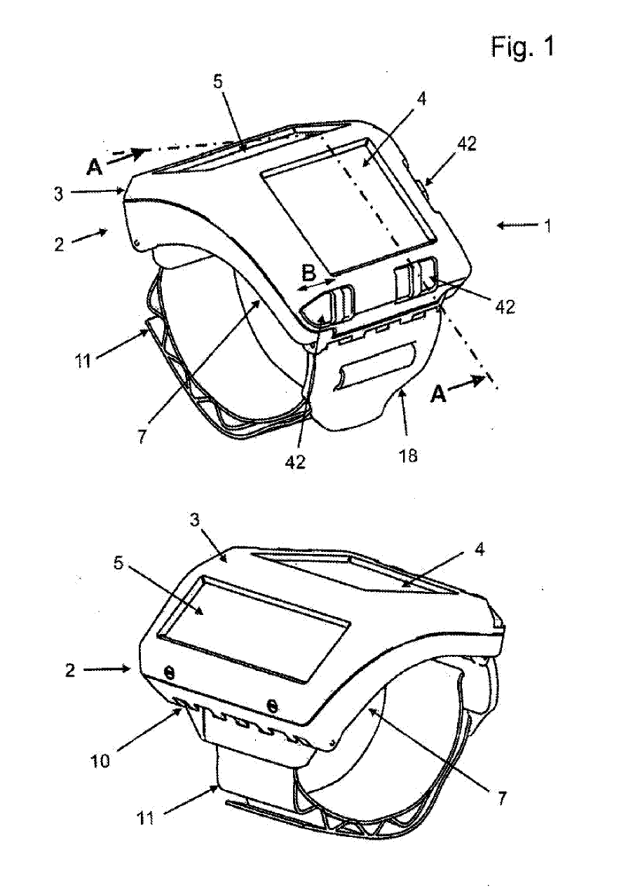

FIG. 1 shows two views of the dive computer with the case in the invention

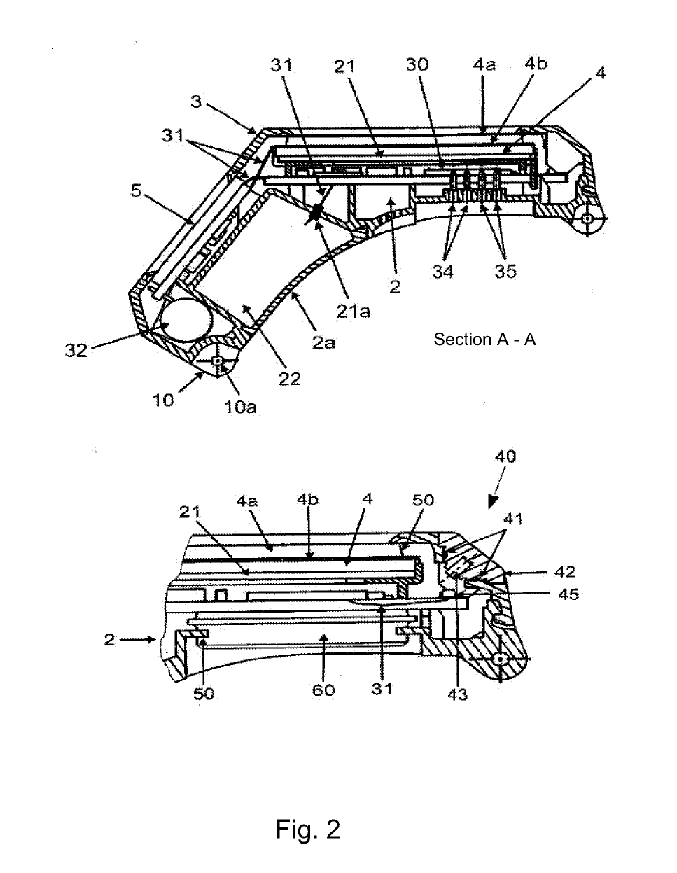

FIG. 2 shows a sectional drawing of the case along line A-A in FIG. 1 and an enlarged cutout of the sectional drawing and

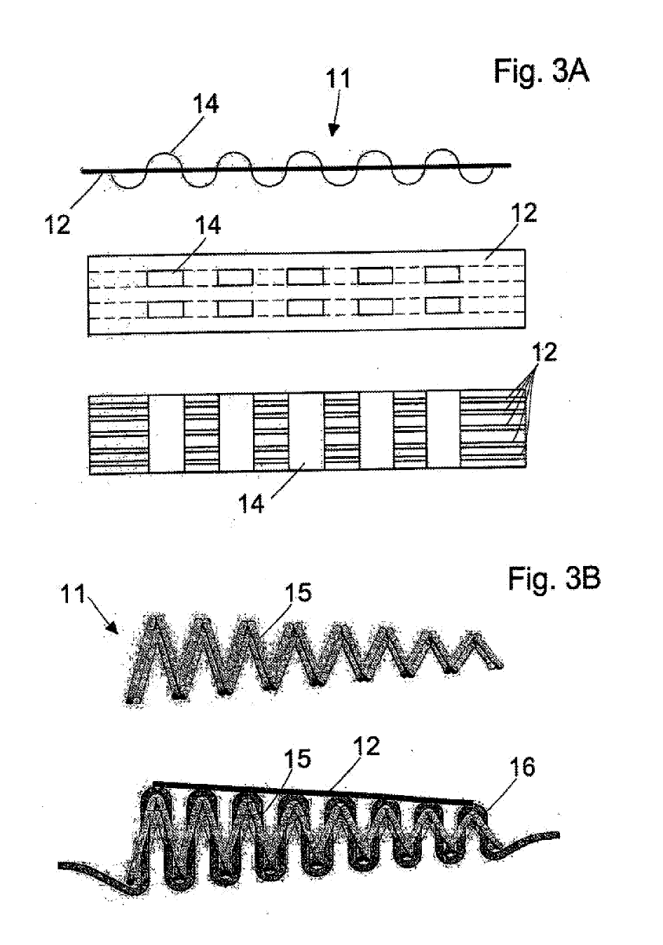

FIG. 3 shows two different embodiments of the bracelet for the dive computer.

FIG. 1 shows a dive computer 1 with the case 2 in the invention in two views. In the example of embodiment, the case 2 is molded of plastic. A crown 3 is placed on the case 2 and is snapped onto it. A display device 4 and a solar element 5 are built into the case 2 so that their outer surfaces close flush with the surface of the case and are thus freely accessible from the outside.

The dive computer 1 shown is attached to the diver's arm so that when the arm is slightly bent, the display device 4 is turned toward the body, hence lies in the diver's field of vision. A lock 18 for the bracelet 11 is also placed on this side facing the body. The case 2 also includes activation devices, whose activation elements 42 can move in translation in the direction of arrow B.

The case 2 includes, on both sides under the display device 4, grid marks 7 which are used to position the dive computer when it is used in a docking station (not shown). On the side facing away from the diver's body, the dive computer includes attachment devices 10 under the solar element 5 for fastening a bracelet 11 to the case 2. On the side of the display device 4 there are corresponding attachment devices to attach the lock 18 for the bracelet 11 of the dive computer 1.

FIG. 2 shows a sectional view of the case 2 along line A-A in FIG. 1, as well as a second view of an enlarged cutout of the right area of this sectional drawing. The case 2 is made so that there are two planes on top that have an angle of approximately 120° between them. The surface of the bottom of the housing 2a has a bend running in the longitudinal direction, which leans on the curved shape of an arm.

The sample case 2 is molded out of a plastic material into which the individual components of the dive computer 1 are built. The case 2 also has hollow spaces 21, which guarantee access to the components behind it. These hollow spaces are closed to the environment by means of a suitable locking system 21 a. The case 2 also has a hollow space 22, into which a battery (not shown) that can be changed by the user is inserted, and it is built into the case 2 so that the hollow space 22 need not be closed to the penetration of water. Completely molded into the case 2 in the example of embodiment are all other functional components of the dive computer, like the computing device 30 or signal and power connection lines 31. Also, a wireless data-transfer device 32 is completely built into the case, while a charging connection 34 for the battery and a wired data-transfer connection on one side 36 are accessible from the outside.

In the example of embodiment, on the component that is accessible from the outside, like, for example the solar element 5, the display device 4 or the charge connection 34, along the edge, there is a glued connection 50 between the case and the components. This connection 50 prevents water from penetrating on the edge of the component into the case even at high water pressures and also ensures a direct transfer of force between the components and the case. At the end of the case 2 facing the solar element 5 (shown in the top figure on the left), there is an attachment device 10 for the bracelet. The attachment device in the example has recesses in the case whose sides are designed as band lugs 10, each of which has an opening 10a for a pin to attach the bracelet. The crown 3 on the case 2 also has built-in transparent scratch protection 4a for the display device 4. To show the touch screen function, under the scratch protection 4a, there is a touch-sensitive sensor 4b.

The enlarged cutout of the end of the sectional view shown on the right shows the activation device 40 for the dive computer in greater detail. The activation device 40 includes an activation element 42 mounted so it can move along two guides 41 built into the case 2, which can be moved in the direction of arrow B shown in FIG. 1. The activation element 42 has no connection to the inside of the case. A permanent magnet 43 is built into the activation element 42.

Moving the activation element 42 also moves the magnetic field produced by the permanent magnets 43.

The activation device 40 also includes a signal unit 45, which is placed completely within the case and which is connected to a signal-processing device by means of connecting lines 31, and is connected to the power supply. The signal unit 45 is formed by a line with current flowing through it in which a magnetic field acting on it produces a voltage. Depending on the position of the activation element 42 to the signal unit 45, a voltage in the signal unit 45 is produced or not.

FIG. 3A shows a first embodiment of a bracelet 11 for the dive computer 1. The bracelet includes several bands or band elements 12, 14 with two different moduli of elasticity. In the form of embodiment shown, the first band 12 is in the relaxed, but not pressed state. The band or band elements 12 have a low modulus of elasticity and are thus very stretchable, whereby the force opposing the stretching is small. To prevent damage to the first band 12 by stretching too hard, it is combined with a second band or band elements 14, which are integrated into the stretchable band folded and unfolded when the band 12 is stretched. The lengths of these bands or band elements are preferably adjusted to one another so that when band 14 is completely unfolded, band 12 is not overstretched and the bracelet 11 moves back into its starting position after the stretching.

A second variation of the bracelet 11 for a dive computer is shown in FIG. 3B.

The top view shows a double coil from an elastic metal alloy 15, into which a band 16 inserted (bottom view). A band element 12 is placed on band 16, which has a high modulus of elasticity and high strength. When the bracelet 11 is tensed, the combination shown elongates until the coil is prevented from further stretching by the band element 12. This embodiment also limits the elasticity of the bracelet without endangering its ability to function.

1. A case for a dive computer, which goes on dives with a diver, with a display device to display dive data, which are visible from outside the case, activation devices of the dive computer, which can be activated outside the case and with attachment devices on the case to attach the dive computer to the diver or his/her gear characterized by the fact that the inside of the case is made to compensate, at least partly, for the forces exerted by the water pressure on the dive computer.

2. The case for the dive computer in claim 1, characterized by the fact that the stationary components of the dive computer are molded completely in the case or molded around it.

3. The case for the dive computer of claim 1, characterized by the fact that the case has functional hollow spaces.

4. The case for the dive computer of claim 1, characterized by the fact that the case is made of a material that can be molded, which is chosen from a group that includes plastic materials, metals and metal alloys.

5. The case for the dive computer of claim 1, characterized by the fact that insulating, damping or sealing elements are placed between the components and the case.

6. The case for the dive computer of claim 1, characterized by the fact that the components or their covering are connected to the case, at least partly, by being glued.

7. The case for the dive computer of claim 1, characterized by the fact that there is a large area of scratch protection on the display device.

8. The case for the dive computer of claim 1, characterized by the fact that the display device has a touch-screen function.

9. The case for the dive computer of claim 1, characterized by the fact that functional and design elements are built onto the outside of the case.

10. The case for the dive computer of claim 1, characterized by the fact that solar cells are built into the surface of the case.

11. The case for the dive computer of claim 1, characterized by the fact that a power supply is placed inside the case and can be charged from the outside.

12. The case for the dive computer of claim 1, characterized by the fact that at least one connecting element is arranged on the case and is used as a power supply for the dive computer.

13. The case for the dive computer of claim 1, characterized by the fact that at least one connecting element is arranged on the case and is used to produce a data connection.

14. The case for the dive computer of claim 1, characterized by the fact that a connecting element is arranged on the case and is used both to produce a data connection with a computer system and also as a power supply.

15. The case for the dive computer of claim 1, characterized by the fact that the case can be used in a docking station, thereby producing a connection to transfer power and/or data.

16. The case for the dive computer of claim 1, characterized by the fact that attachment elements are molded directly in the case.

17. The case for the dive computer of claim 1, characterized by the fact that an elastic bracelet is used to attach the case to the diver.

18. A bracelet for the dive computer whose case is made according to claim 1, characterized by the fact that the elasticity of the bracelet lies in the range from 0.1 to 0.001 GPa, especially in the range from 0.001 to 0.0001 GPa.

19. The bracelet for the dive computer in claim 18, characterized by the fact that the bracelet includes several bands or band elements.

20. The bracelet for the dive computer in claim 18, characterized by the fact that the bracelet has an elastic coil made of a metal alloy.

21. The bracelet for the dive computer in claim 19, characterized by the fact that at least one second band element is built into the bracelet and is made of a material that has low elasticity but high strength.

22. The bracelet for the dive computer in claim 21, characterized by the fact that there is at least one second band element pressed in the longitudinal direction when the bracelet is in the unstressed state.

23. An activation device for a dive computer whose case is made according to claim 1, characterized by the fact that the activation device has a signal unit that is placed in a closed case, which has an activation element separate from it that is placed in the area outside the case.

24. The activation device for the dive computer in claim 23, characterized by the fact that the signal unit includes a conductor with current flowing through it and the activation element includes a permanent magnet.

25. The activation device for the dive computer in claim 23, characterized by the fact that when the dive computer is activated, at least one of at least two signal units are in the magnetic field of an activation element.

26. The case for a dive computer of claim 2, characterized by the fact that:
the case has functional hollow spaces;
the case is made of a material that can be molded, which is chosen from a group that includes plastic materials, metals and metal alloys;
insulating, damping or sealing elements are placed between the components and the case;
the components or their covering are connected to the case, at least partly, by being glued;
there is a large area of scratch protection on the display device;
the display device has a touch-screen function;
functional and design elements are built onto the outside of the case;
solar cells are built into the surface of the case;
a power supply is placed inside the case and can be charged from the outside;
the case can be used in a docking station, thereby producing a connection to transfer power and/or data;
attachment elements are molded directly in the case; and
an elastic bracelet is used to attach the case to the diver.

27. The case for a dive computer of claim 26, characterized by the fact that:
at least one connecting element is arranged on the case and is used as a power supply for the dive computer; and
at least one connecting element is arranged on the case and is used to produce a data connection.

28. The case for a dive computer of claim 26, characterized by the fact that a connecting element is arranged on the case and is used both to produce a data connection with a computer system and also as a power supply.

29. A bracelet for the dive computer whose case is made according to claim 26, characterized by the fact that:
the elasticity of the bracelet lies in the range from 0.1 to 0.001 GPa, especially in the range from 0.001 to 0.0001 GPa;
the bracelet includes several bands or band elements;
at least one second band element is built into the bracelet and is made of a material that has low elasticity but high strength; and
there is at least one second band element pressed in the longitudinal direction when the bracelet is in the unstressed state.

30. A bracelet for the dive computer in claim 29, characterized by the fact that the bracelet has an elastic coil made of a metal alloy.

31. An activation device for a dive computer whose case is made according to claim 26, characterized by the fact that:
the activation device has a signal unit that is placed in a closed case, which has an activation element separate from it that is placed in the area outside the case;
the signal unit includes a conductor with current flowing through it and the activation element includes a permanent magnet; and
when the dive computer is activated, at least one of at least two signal units are in the magnetic field of an activation element.
